(19) United States
(12) Patent Application Publication
(10) Pub. No.: US 2016/0126265 A1
(43) Pub. Date: May 5, 2016

(54) IMAGE SENSOR HAVING IMPROVED QUANTUM EFFICIENCY AT LARGE WAVELENGTHS

(71) Applicant: E2V SEMICONDUCTORS, Saint-Egreve (FR)

(72) Inventors: Thierry LIGOZAT, QUAIX EN CHARTREUSE (FR); Pierre FEREYRE, VOREPPE (FR); Frederic MAYER, VOIRON (FR)

(21) Appl. No.: 14/436,509

(22) PCT Filed: Oct. 16, 2013
(86) PCT No.: PCT/EP2013/071636

§ 371 Date: Apr. 17, 2015

(30) Foreign Application Priority Data
Oct. 18, 2012 (FR) 1259947

(51) Int. Cl. H01L 27/146

(52) U.S. Cl. CPC H01L 27/1461; H01L 27/14643; H01L 27/1464

(57) ABSTRACT

The invention relates to an image sensor specially adapted to vision in low-light conditions (notably night vision).The sensor is formed on an integrated circuit chip starting from a silicon substrate. It comprises: a matrix of rows and columns of active pixels each comprising at least one photodiode and transistors, control circuits for the matrix, external to the matrix, and signal read circuits, external to the matrix. The photodiodes of the sensor are formed within an active layer of single-crystal silicon whose resistivity is at least 500 ohms·cm if this active layer is an epitaxial layer grown on the silicon substrate and at least 2000 ohms·cm if this active layer consists of the upper part of the silicon substrate. The control circuits and the read circuits of the sensor are formed in at least one doped global well, of the same type as the active layer of single-crystal silicon and having a resistivity lower than or equal to 30 ohms·cm, this well being formed within the active layer and not including the matrix.

### FIELD

The invention relates to image sensors using CMOS technology on a silicon substrate.

### BACKGROUND

A high-performance image sensor must comply with numerous contradictory constraints: reduction in the size of the pixels to improve the resolution and the volume or the cost of fabrication; however, installation of several transistors within each pixel for reading the signal notably in instantaneous image acquisition mode (‘snapshot’ mode, with integration time common to all the rows of pixels); high storage capacity for electrons within each pixel for maximizing the linear measurement dynamic range of illumination without saturation of the pixels; maximum sensitivity for low-lighting conditions with as low noise as possible, etc.

At night, the light originates either from the moon, or, in the absence of a moon, from the “night glow” of the sky, originating from far-away galaxies and also from the reflection of sunlight on the particles dispersed in atmospheric or interplanetary space. The night glow or lunar light emission spectrum can be measured and may be expressed in the number of photons received per second and per square centimeter for a given segment of wavelengths (for example in 10 nanometer segments).

Typically, the spectrum of the lunar reflection is more or less uniform, in the visible region and the near-infrared, but the night glow light emission in the absence of a moon is much weaker in the visible range than in the near-infrared.

In the absence of a moon, the number of photons received at night by a pixel of 5×5 micrometers may be estimated at 5 to 15 for an exposure time of 1/25 of a second to 1/60 of a second in other words for the duration of a conventional frame of a video image. These photons are in the main in the near-infrared and not in the visible wavelengths.

It is therefore important, for the acquisition of an image in low-light and notably in night vision mode, to increase the sensitivity of the detector in the near-infrared as much as possible, given furthermore that the silicon exhibits a capacity for conversion of photons into electrons up to wavelengths that can reach 1100 nanometers.

One aim of the invention is therefore to improve the quality of image sensors by improving the quantum efficiency of the detection, in other words the ratio between the number of electron charges collected in a photosensitive surface and the number of photons received by this surface, in the near-infrared (from around 750 nanometers to 1100 nanometers), without affecting the detection in the visible range (from around 400 nanometers to 800 nanometers), while at the same time conserving a technological compatibility with the fabrication of electronic processing circuits formed on the same integrated circuit chip as the sensor.

### SUMMARY

For this purpose, the invention provides an image sensor formed on an integrated circuit chip starting from a silicon substrate of a first type of conductivity, comprising:

a matrix of rows and columns of active pixels each comprising at least one photodiode and transistors formed in an active layer of single-crystal silicon of the first type of conductivity formed on the surface of the substrate,

portions of control circuits for the matrix, external to the matrix, and portions of signal read circuits, external to the matrix,

this sensor being characterized in that the active layer of single-crystal silicon has a resistivity of at least 500 ohms·cm if this active layer is an epitaxial layer grown in contact with the silicon substrate of the first type of conductivity and of at least 2000 ohms·cm if this active layer is formed directly by the upper part of the silicon substrate, and in that the portions of control circuits and the read circuits are formed within at least one doped global well, of the same type as the active layer of single-crystal silicon and having a resistivity of at the most 40 ohms·cm, this well being formed within the active layer and not including the matrix of pixels.

The well formed within this layer starts from the surface of the active layer, whether it is an epitaxial layer or otherwise, and preferably has a depth of a few micrometers (preferably around 2 to 5 micrometers) in order to allow a normal operation of the MOS transistors. This layer itself contains the wells to be used for the formation of the CMOS technology elements (transistors, capacitors, diodes, etc.). If the active layer of single-crystal silicon is an epitaxial layer, the thickness of this layer is preferably in the range between 10 micrometers and 50 micrometers; the well does not therefore extend over the whole depth of the epitaxial active layer.

This structure clearly divides the image sensor chip into a region reserved for the matrix and a region reserved for the electronic control and read circuits external to the matrix; these regions are distinguished by the different doping of the active layer, since the active layer in the region reserved for the control and read circuits has a much lower resistivity (that of the doped well) than the active layer in the area reserved for the matrix of pixels. There is a direct link between the doping and the resistivity, the resistivity being lower the higher the doping.

This allows, in particular, control and read circuits to be formed which operate correctly, with a higher reliability than if these circuits were formed directly within an active layer whose resistivity would have been greatly increased for reasons linked to the correct operation of the matrix of pixels. In particular, the structures for protection against electrostatic discharges will be better controlled.

If the matrix of pixels is formed within an epitaxial active layer, a resistivity of active layer of 500 to 2000 ohms·cm will preferably be chosen. If it is formed directly within the upper part of a non-epitaxial silicon substrate (substrate obtained by drawing an ingot and sawing the ingot without epitaxy on the sawn section), a resistivity of 5000 to 10 000 ohms·cm will preferably be given to the substrate.

It will be noted that the invention is also applicable in the case of a thinned sensor illuminated by its back face, in other words a sensor in which all or almost all of the starting silicon substrate has been eliminated by its back face, only conserving the active layer itself transferred by its front face onto another substrate (carrier substrate). In this case, it is the sensitivity in the blue rather than in the near-infrared which may be improved.

### BRIEF DESCRIPTION OF DRAWINGS

Other features and advantages of the invention will become apparent upon reading the detailed description that follows and which is presented with reference to the appended drawings in which:

FIG. 1 shows schematically a top view of an integrated image sensor on silicon comprising a matrix of pixels and electronic circuits external to the matrix;

FIG. 2 shows a global well, diffused into a layer of the same type of conductivity but less doped, the well not encompassing the region corresponding to the matrix of pixels;

FIG. 3 shows one variant embodiment in which the well does not encompass either the matrix or a grounding ring for the substrate surrounding the matrix, nor does it encompass a protection ring surrounding the matrix;

FIG. 4 shows a cross section of the sensor at the border between the matrix and the global well;

FIG. 5 shows the curves of quantum efficiency as a function of wavelength for a pixel according to the invention and a pixel using conventional technology.

### DESCRIPTION OF EMBODIMENTS

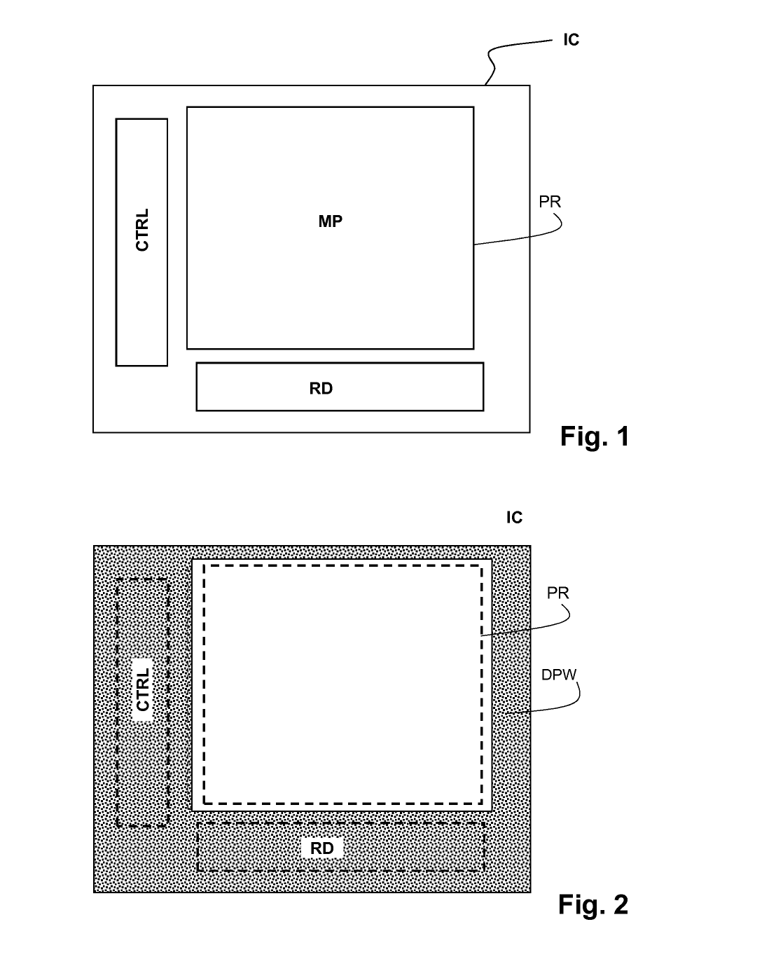

FIG. 1 shows the conventional design of an image sensor formed on an integrated circuit chip IC; it comprises a matrix MP of rows and columns of active pixels, each pixel comprising a photodiode and MOS transistors. The transistors are used to select the pixel, to control the start and end of the integration time, and to convert a quantity of photo-generated charges into a voltage level representing the illumination of the pixel. Externally to the matrix, there are electronic circuits which may be globally divided into two categories: control circuits CTRL and read circuits RD. The control circuits CTRL notably comprise sequencers and row addressing circuits for the selection of the pixels row by row, etc. The read circuits RD comprise sampling circuits which collect the analogue voltage levels produced by the pixels, and analogue-digital conversion circuits; they may also comprise other signal processing functions.

In the prior art, the integrated circuit is formed starting from a highly-doped silicon substrate with a low resistivity (for example of 1 to 50 milliohms·cm), covered by an active layer of single-crystal silicon which is an epitaxial layer that is less doped and therefore of higher resistivity (typically of 5 to 30 ohms·cm). It is assumed in the following that the active epitaxial layer is of the P type, but it could be of the N type, and in this case all the types of conductivity which are now going to be indicated need to be reversed.

Within the active layer are formed:

the photodiodes of the pixels (diffusion of the N type into the active layer of the P type, the diffusion of the N type usually being covered by a surface layer of the P type),

the other circuit elements of the pixel, for example the sources and drains of NMOS transistors of the pixel,

the NMOS transistors and other circuit elements forming part of the control circuits CTRL and of the read circuits RD; the PMOS transistors of the circuits CTRL and RD are formed within shallow (maximum 1 micrometer in depth) individual wells (one well per transistor) of the N type diffused into the active layer,

the MOS capacitors and the diodes.

The thickness of the active epitaxial layer in the structure of FIG. 1 is around 5 to 10 micrometers.

According to the invention, the photodiodes are first of all formed within an active layer of single-crystal silicon which has a much higher resistivity than in the prior art, typically a resistivity of at least 500 ohms·cm for the epitaxial layer, this being at least 20 to 50 times higher than in the prior art. In addition, the control circuit CTRL and read circuit RD, and more generally all the electronic circuits situated outside of the perimeter PR of the matrix of pixels, are placed within at least one deep global well DPW of the P type (for an active layer of the P type) shown in the dashed area in FIG. 2. This well is deeper than the individual wells of the N type for the PMOS transistors of the circuits. Its depth is preferably 2 to 4 micrometers as a minimum, but in any case less than or equal to the depth of the active epitaxial layer. Its doping, higher than that of the active layer, is such that it has a resistivity much lower than that of the active layer; the resistivity of the global well DPW is at the most 30 ohms·cm and preferably in the range between 5 and 10 ohms·cm. The well does not encompass the surface of the matrix MP nor even a part of the matrix; in other words the edges of the well stop, when going from the outside towards the inside of the matrix, before the perimeter PR of the matrix, as can be seen in FIG. 2. The well, the active layer and the substrate are of the same type of conductivity, here P type.

The control and read circuits CTRL and RD external to the matrix, or at least portions of these circuits, are included within the global well DPW of the P type and the PMOS transistors of these circuits are formed within individual wells of the N type shallower than the global well DPW. The individual wells of the N type can have a depth of around 1 micrometer. The term ‘global well’ is understood to mean that wide portions of circuit including numerous transistors and other circuit elements are included within the same well. FIG. 2 shows only one global well, but it will be understood that, for practical reasons, it could be envisioned to subdivide this well into several different global wells, for example one respective global well for the circuits CTRL and another for the circuits RD. It could also be that certain elements of these circuits are formed within a deep well of the N type, but the invention is concerned here with those of the circuit elements that are formed within a deep well of the P type of the same type as the active layer but with a different doping.

In a first embodiment, the active layer is an epitaxial layer; this layer is formed on a silicon substrate which is a section sawn in an ingot of silicon formed by drawing from within a bath of molten silicon. The surface of the section is polished. The epitaxial layer is much less doped than the substrate. The latter is of the same type of conductivity as the active layer; it is preferably of the P type and highly-doped.

In a second embodiment, the active layer is not formed by an epitaxial layer grown on the surface of the substrate, but it is formed by the upper part of the substrate itself formed by the section sawn from the ingot of silicon; in this case, the resistivity of the active layer (here again of the same type of conductivity as the substrate) is preferably even higher; it is at least 2000 ohms·cm and preferably higher than 5000 ohms·cm. The ingot of silicon is prepared with the weak doping which leads to this high resistivity.

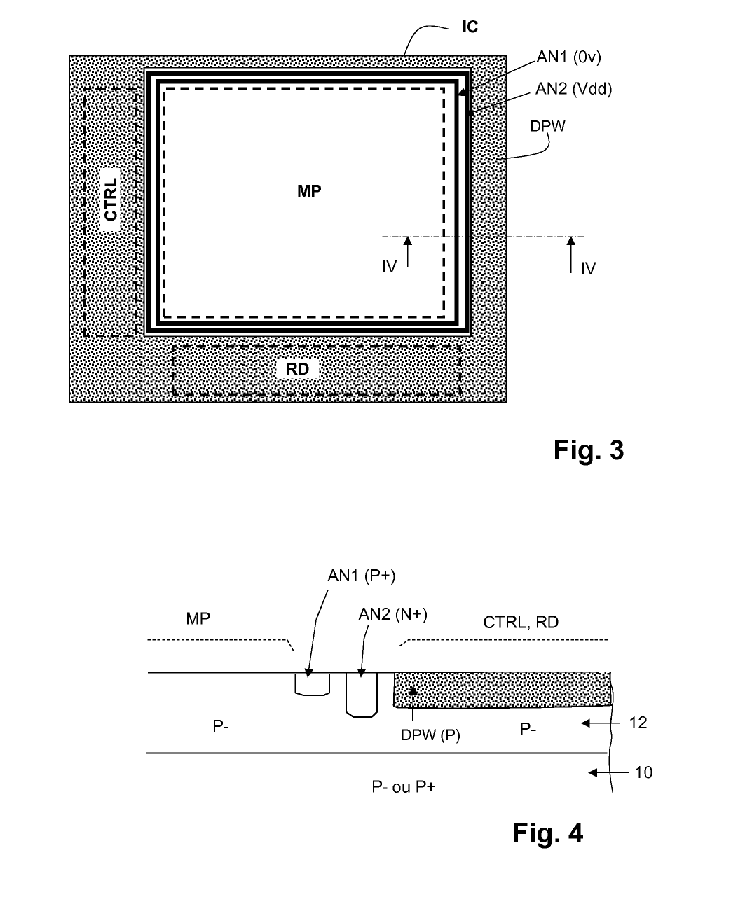

In both cases, preferably, as shown in FIG. 3, the matrix of pixels is surrounded by two concentric peripheral rings AN1 and AN2, and the well DPW does not encompass either the matrix or these two peripheral rings. The inner ring AN1, closer to the perimeter PR of the matrix, is composed of a diffusion of the P type, highly doped and electrically connected to a ground; its purpose is to fix the potential of the active layer at zero within the whole region of the matrix MP so as to form a ground plane. The outer ring AN2 is a diffusion of the N type which is highly doped and connected to a general positive power supply potential Vdd; its purpose is to create a deep depletion region which tends to prevent spurious charges from propagating from the exterior towards the interior of the matrix region MP.

FIG. 4 shows a cross section of the sensor structure according to the invention, this cross section being taken along the line IV-IV in FIG. 3, in the region of the border between the matrix MP and the deep global well DPW. The structure comprises a silicon substrate 10 of the P type (eliminated during the fabrication in the case of a thinned sensor illuminated by the back face), and an active layer 12 of single-crystal silicon of the same type but weakly doped (P−) in the upper part of the substrate. The peripheral rings AN1 of the P+ type and AN2 of the N+ type are diffused starting from the surface.

The matrix of pixels is formed within the region MP surrounded by the peripheral rings, using the weakly-doped silicon of the P− type of the active layer in order to form the anode of the photodiodes; the cathode is formed by a surface diffusion of the N type in this active layer, and this diffusion may itself be covered by a surface diffusion of the P type electrically connected to the anode. The channel regions of the transistors of the pixels are formed by the active layer (whose doping can be locally adjusted in order to set the threshold voltage).

The read circuit RD and control circuit CTRL are formed within the well DPW of the P type, external to the matrix and to the peripheral rings and more highly doped than the active layer. The channel region of the NMOS transistors of these circuits consists of the global well DPW (or of specific wells) potentially with a local adjustment of the doping in order to set the threshold voltage; the PMOS transistors of these circuits are formed in individual shallow wells (of around 1 micrometer) of the N type, shallower than the global well, diffused starting from the surface of the global well; the channel region of these PMOS transistors consists of the individual wells; here again, the doping of the channel can be adjusted in order to set the threshold voltage.

In the first embodiment of the invention, the active layer of single-crystal silicon is an epitaxial layer deposited on a silicon highly-doped substrate of the same type of conductivity having a resistivity of 1 to 20 milliohms·cm. The epitaxial layer has a depth preferably greater than 10 micrometers and preferably in the range between 10 and 50 micrometers. Its resistivity is higher than 500 ohms·cm and preferably in the range between 500 and 3000 ohms·cm.

In the second embodiment, which does not have an epitaxial layer, the active layer is formed by the substrate of single-crystal silicon itself and is of the same type of conductivity as the substrate. In this case, the substrate is weakly-doped, its resistivity being at least 2000 ohms·cm and preferably in the range between 5000 ohms·cm and 10 000 ohms·cm. The thickness of the substrate can be 700 micrometers for example for a non-thinned sensor.

In the two embodiments, the image sensor may be of the thinned type and illuminated by the back face, in other words, after the formation of the matrix MP and of the electronic circuits on the front face of the active layer, the silicon substrate is bonded by this front face onto a carrier substrate, then the back face of the starting substrate is thinned until only the active layer (epitaxial or otherwise) remains with a thickness of a few micrometers to a few tens of micrometers. It is the carrier substrate that provides the mechanical strength during the fabrication and after the fabrication.

In the case of an illumination by the front face, and owing to the high resistivity of the silicon of the active layer, the depletion region which is naturally formed under the photodiodes is deeper, which very substantially improves the collection of the electrical charges generated by the photons at depth. As the longest wavelengths to which the silicon is sensitive penetrate more deeply into the silicon, their contribution to the production of electrons is very efficient without these electrons being dispersed into the substrate towards neighboring pixels. The spatial resolution is improved as a result. This especially relates to the wavelengths of the near-infrared, given that silicon is photosensitive within a range of wavelengths going from 250 nanometers (near-ultraviolet) to just over 1050 nanometers (near-infrared). The depth of the active layer (in the case where it consists of an epitaxial layer or in the case of a thinned sensor, is chosen to be sufficient to be able to best sense the wavelengths going from 800 to 1100 nanometers; this depth is then chosen to preferably be greater than 15 micrometers or, even better, greater than 30 micrometers, whereas, in the prior art, it is usually less than 5 micrometers. With a depth greater than 15 micrometers, or better 30 micrometers, it is considered that a large proportion of the photons with wavelengths going from around 800 nanometers to 1100 nanometers can be sensed.

The capability for measuring low-level light going from the red to the near-infrared is therefore superior than in the prior art, a fact which is important for night vision, and this is achieved without deteriorating the qualities of the electronic control and read circuits. These circuits would indeed operate less efficiently if they were formed directly within a substrate that were too resistive. This is the case, in particular, for the voltage reference circuits, being indispensible in the electronic circuits of the sensor, which would not work well if they were formed directly within an active layer of resistivity higher than 500 ohms·cm. This may also be the case for resistors formed within the substrate or for capacitors one plate of which is formed by the substrate and whose dielectric is linked to the depletion of the substrate, for bipolar transistors, etc.

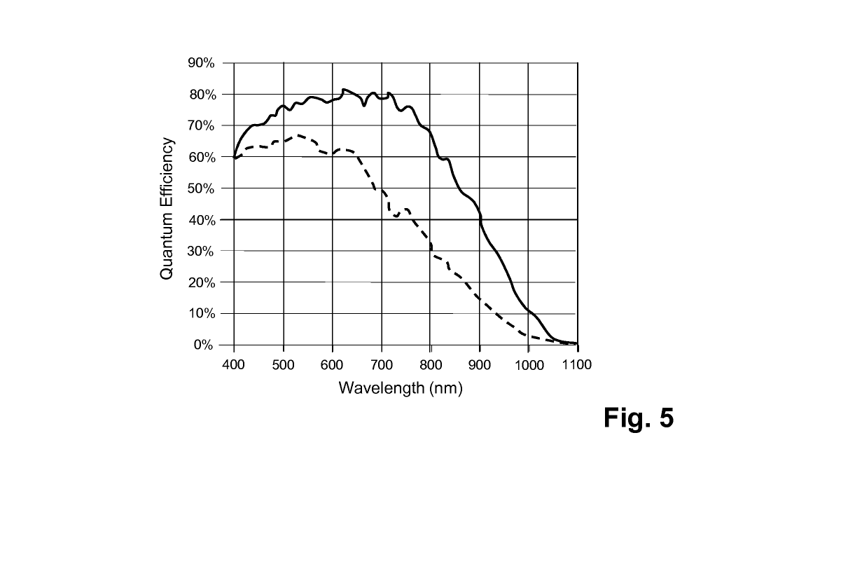

FIG. 5 presents, by way of illustration, a solid curve representing the quantum efficiency for a pixel according to the invention of 5.3 micrometers on a side illuminated by the front face and covered by a microlens. By comparison, the dashed curve represents the quantum efficiency for a similar pixel but using a standard technology.

1. An image sensor formed on an integrated circuit chip starting from a silicon substrate of a first type of conductivity, comprising:
a matrix of rows and columns of active pixels each comprising at least one photodiode and transistors formed in an active layer of single-crystal silicon of the first type of conductivity formed on a surface of the substrate,
control circuits for the matrix, external to the matrix, and signal read circuits, external to the matrix,
wherein the active layer of single-crystal silicon has a resistivity of at least 500 ohms·cm if said active layer is an epitaxial layer grown in contact with the silicon substrate of the first type of conductivity and of at least 2000 ohms·cm if said active layer consists of the upper part of the silicon substrate, and wherein the control circuits and the read circuits are formed within at least one doped global well, of the first type of conductivity and having a resistivity lower than or equal to 30 ohms·cm, said well being formed within the active layer with a continuity of type of conductivity between the well and the active layer and the well not including the matrix of pixels.

2. The image sensor as claimed in claim 1, wherein the well has a depth of around 2 to 5 micrometers starting from a surface of the active layer.

3. The image sensor as claimed in claim 1, wherein the active layer of single-crystal silicon is an epitaxial layer with a resistivity in a range between 500 and 2000 ohms·cm.

4. The image sensor as claimed in claim 3, wherein a thickness of the epitaxial layer is in a range between 10 micrometers and 50 micrometers.

5. The image sensor as claimed in claim 1, wherein the active layer consists of the upper part of a non-epitaxial silicon substrate of resistivity in a range between 5000 and 10 000 ohms·cm.

6. The image sensor as claimed in claim 1, designed to be illuminated by a back face, in which all or almost all of the silicon substrate, on the active layer of which the matrix of pixels has been formed, has been eliminated, only conserving the active layer itself transferred onto another substrate.

7. The image sensor as claimed in claim 2, wherein the active layer of single-crystal silicon is an epitaxial layer with a resistivity in a range between 500 and 2000 ohms·cm.

8. The image sensor as claimed in claim 7, wherein a thickness of the epitaxial layer is in a range between 10 micrometers and 50 micrometers.

9. The image sensor as claimed in claim 2, wherein the active layer consists of the upper part of a non-epitaxial silicon substrate of resistivity in a range between 5000 and 10 000 ohms·cm.

10. The image sensor as claimed in claim 2, designed to be illuminated by a back face, in which all or almost all of the silicon substrate, on the active layer of which the matrix of pixels has been formed, has been eliminated, only conserving the active layer itself transferred onto another substrate.

11. The image sensor as claimed in claim 3, designed to be illuminated by a back face, in which all or almost all of the silicon substrate, on the active layer of which the matrix of pixels has been formed, has been eliminated, only conserving the active layer itself transferred onto another substrate.

12. The image sensor as claimed in claim 5, designed to be illuminated by a back face, in which all or almost all of the silicon substrate, on the active layer of which the matrix of pixels has been formed, has been eliminated, only conserving the active layer itself transferred onto another substrate.
